(19) United States
(12) Patent Application Publication
(10) Pub. No.: US 2026/0278205 A1
(43) Pub. Date: Sep. 17, 2026

(54) Weather Pattern Recognition Systems and Methods for Recognition-Based Meteorological Data Processing, Pattern Detection, Forecast Generation, Ensemble Weighting, and Alert Scoring

(71) Applicant: Jonathan Washburn, Austin, TX (US)

(72) Inventor: Jonathan Washburn, Austin, TX (US)

(21) Appl. No.: 19/565,336

(22) Filed: Mar. 12, 2026

Related U.S. Application Data
(60) Provisional application No. 63/771,426, filed on Mar. 13, 2025.

(51) Int. Cl. G06F 30/20; G06F 16/29

(52) U.S. Cl. CPC G06F 30/20; G06F 16/29

(57) ABSTRACT

Systems and methods are disclosed for recognition-based meteorological data processing, pattern detection, forecast generation and update, ensemble weighting, and hazard alert scoring. Meteorological data representing one or more meteorological fields are received, and one or more nonnegative recognition metrics are determined from observational inputs, derived fields, model outputs, or verification metrics. A bounded, monotone recognition coverage function is applied to compute a recognition weight, the recognition coverage function being defined as ‘F_cov(r)=r/(r+X_opt)’, where ‘r’ is the nonnegative recognition metric and ‘X_opt’ is a positive constant, including embodiments where ‘X_opt=phi/pi’ and ‘phi=(1+sqrt(5))/2’. The recognition weight is applied to filter meteorological fields, generate pattern match confidence, scale forecast update terms using stability context, compute ensemble blending weights from skill metrics, and compute confidence-weighted hazard alert scores from intensity measures. The techniques are implementable using one or more processors and memory.

### CROSS-REFERENCE TO RELATED APPLICATIONS

This application claims the benefit of U.S. Provisional Patent Application No. 63/771,426, filed Mar. 13, 2025, the entirety of which is incorporated herein by reference to the extent permitted; however, any incorporation by reference is not intended to substitute for the express disclosure of any subject matter required to satisfy 35 U.S.C. § 112, and all such subject matter is expressly set forth in this application.

### BACKGROUND OF THE INVENTION

The present disclosure relates to meteorological data processing and forecasting. More particularly, the present disclosure relates to computer-implemented systems and methods that apply bounded, monotone recognition-weighting transforms to meteorological data fields, pattern detection and classification, forecast generation and update, ensemble and model weighting, and hazard alert scoring.

Modern meteorological forecasting pipelines frequently combine heterogeneous observational inputs with numerical weather prediction models and downstream post-processing. Observational inputs may include satellite-derived fields, weather radar products, radiosonde measurements, surface station measurements, aircraft-based observations, marine buoy measurements, lightning networks, and other sensor-derived data streams. Numerical weather prediction may provide multi-variable fields such as pressure, temperature, humidity, wind components, geopotential height, and derived quantities over a forecast horizon. Weather products may be represented as gridded data, three-dimensional volumes, vertical profiles, tiles, image products, object tracks, polygon regions, or combinations thereof.

In operational practice, forecast performance and interpretability may degrade due to limitations associated with incomplete coverage, variable-quality sensor measurements, representativeness error, spatial and temporal alignment challenges, and the inherently chaotic and multi-scale dynamics of atmospheric systems. Forecast uncertainty may grow with time, and forecast skill may depend strongly on region, season, hazard class, atmospheric regime, data availability, and sensor quality.

Data assimilation systems, including variational and ensemble-based assimilation schemes, may incorporate observational inputs into model state estimates. In some workflows, observation weighting and quality control may be uniform or only coarsely adjusted, and quality variation may be handled by hard rejection rules or coarse thinning. Such approaches can be suboptimal when observation reliability varies materially across time, space, sensors, retrieval modes, and regimes, potentially leading to insufficiently weighted high-quality observations or overly weighted low-quality observations.

Pattern detection and classification for meteorological hazards may be implemented using rule-based thresholds, correlation-based matching, heuristic tracking, or machine-learning approaches. Thresholding methods may be brittle when applied across regimes and may generate false positives in low-confidence conditions or miss hazards that present differently than expected. Machine-learning methods can require large labeled datasets, may be sensitive to distribution shift, may be difficult to calibrate and interpret, and may not inherently encode quality-aware or confidence-aware weighting across heterogeneous input sources and model outputs.

Ensemble forecasting methods may provide multiple model members or multiple models, each producing candidate forecasts. In practice, ensemble members may be equally weighted or blended using static weighting approaches that do not reflect real-time skill variations by regime, region, variable, lead time, hazard class, or model version. Static weighting can limit the benefits of ensemble diversity and may fail to suppress systematically underperforming members in specific contexts while over-trusting members that are temporarily inconsistent with observations.

Operational alerting and hazard decision-support may compute alert scores and issue notifications based on intensity measures and thresholds. Such workflows may not consistently incorporate confidence, observation quality, pattern match strength, stability context, or ensemble agreement, which can lead to excessive alert frequency, reduced trust, alert fatigue, or missed hazards. In many operational environments, explainability and auditability are also needed so that a downstream user can understand why a given alert was issued or suppressed.

Accordingly, there remains a need for improved meteorological processing and forecasting systems that provide consistent, computationally efficient, bounded and monotone weighting behavior across data filtering, pattern detection, forecast update, ensemble weighting, and alert scoring, and that can be implemented in practical computing environments without requiring extensive empirical tuning for each hazard type, sensor type, variable, or atmospheric regime.

In various embodiments, the disclosed recognition coverage function and recognition-derived weights provide a technical improvement in meteorological computing workflows by bounding the influence of low-confidence inputs and unstable updates while maintaining sensitivity to high-confidence inputs. In some embodiments, this bounded and monotone behavior improves numerical stability and operational consistency across heterogeneous sensors and models, reduces false-alarm behavior in low-confidence conditions, and improves interpretability by producing explainable, audit-ready intermediate weights that can be logged and reviewed.

### SUMMARY OF THE INVENTION

The present disclosure provides computer-implemented systems and methods for meteorological data processing and forecasting that apply a bounded, monotone recognition weighting function to one or more recognition metrics derived from meteorological observations, derived fields, model outputs, verification metrics, or combinations thereof. In various embodiments, recognition weights are used to filter meteorological data fields, compute pattern match confidence, scale forecast update derivatives using stability context, compute ensemble weights from skill metrics, and compute confidence-aware alert scores.

In some embodiments, a recognition coverage function is defined as F_cov(r)=r/(r+X_opt), where r is a nonnegative recognition input metric and X_opt is a positive constant. In some embodiments, X_opt is defined as X_opt=phi/pi, where phi=(1+sqrt(5))/2 and pi is the ratio of a circle's circumference to its diameter.

In some embodiments, for r>=0, the function F_cov(r) is bounded and monotone with F_cov(0)=0 and F_cov(r) approaching 1 as r increases without bound. In various embodiments, this behavior provides a non-amplifying weight that suppresses low-confidence contributions while asymptotically preserving high-confidence contributions. In some embodiments, the same recognition coverage function is used at multiple stages of an end-to-end meteorological pipeline such that the system exhibits consistent weighting behavior for heterogeneous inputs and downstream products.

In some embodiments, recognition input metrics r are derived from one or more raw metrics including, by way of example and without limitation, signal-to-noise ratio metrics, sensor confidence scores, retrieval confidence values, temporal consistency metrics, neighborhood consistency metrics, cross-sensor agreement metrics, inverse error metrics, innovation consistency metrics, ensemble spread inverse metrics, forecast skill metrics, regime similarity metrics, pattern match confidence metrics, stability metrics, persistence metrics, or combinations thereof.

In some embodiments, raw metrics are mapped into a nonnegative recognition metric space prior to application of the recognition coverage function. By way of example, r may be computed as r=max(0, m_raw), r=abs(m_raw), r=(m_raw−m_min)/(m_max−m_min) followed by r=max(0, r), or r=1/(epsilon+e_raw), where epsilon is a small positive constant.

In some embodiments, a recognition atmospheric data filter applies recognition weights to meteorological data fields to generate recognition-filtered fields. In some embodiments, D_rec(x,y,z,t)=D(x,y,z,t)*F_cov(r_data(x,y,z,t)), where D is a meteorological data field and r_data is a data recognition metric.

In some embodiments, a recognition pattern matching engine compares recognition-filtered fields against stored pattern representations to produce match scores and confidence outputs. In some embodiments, a recognition stability scoring engine computes stability recognition metrics from one or more stability-related variables and computes stability weights used to gate or scale forecast update derivatives.

In some embodiments, a recognition predictive forecasting engine computes temporal derivatives based on recognition-filtered fields and scales one or more derivatives using stability weights to generate bounded forecast updates. In some embodiments, a recognition ensemble weighting engine converts skill metrics for models or ensemble members into normalized weights using the recognition coverage function and blends model outputs accordingly. In some embodiments, a recognition alert engine computes alert scores based on an intensity measure and a recognition-derived confidence weight, thereby suppressing low-confidence alert outputs while preserving high-confidence alert outputs.

In various embodiments, the systems and methods described herein are implemented as one or more of: (i) a method performed by one or more processors; (ii) a system comprising one or more processors and memory storing instructions; (iii) an apparatus; and (iv) a non-transitory computer-readable medium storing instructions that cause one or more processors to perform the described operations.

### BRIEF DESCRIPTION OF THE DRAWINGS

The accompanying drawings, which form a part of this disclosure, illustrate various embodiments and, together with the description, further serve to explain the principles of the invention and to enable a person skilled in the relevant art(s) to make and use the invention.

FIG. 1 is a block diagram illustrating an example meteorological recognition processing system including data ingestion, a recognition atmospheric data filter, a recognition pattern matching engine, a recognition stability scoring engine, a recognition predictive forecasting engine, a recognition ensemble weighting engine, and a recognition alert engine.

FIG. 2 is a plot illustrating an example recognition coverage function F_cov(r)=r/(r+X_opt) and example properties of boundedness and monotonicity.

FIG. 3 is a flow diagram illustrating an example pipeline for transforming one or more raw metrics into a nonnegative recognition metric r, computing a recognition weight F_cov(r), and applying the recognition weight to downstream operations.

FIG. 4 is a flow diagram illustrating an example recognition atmospheric data filtering process for generating a recognition-filtered meteorological field.

FIG. 5 is a flow diagram illustrating an example recognition pattern matching process using recognition-filtered meteorological fields and stored pattern representations.

FIG. 6 is a flow diagram illustrating an example stability metric generation process and derivative-scaling forecast update process.

FIG. 7 is a flow diagram illustrating an example ensemble or model weighting process using recognition-derived weights computed from skill metrics, and further illustrating generation of one or more blended forecast outputs.

FIG. 8 is a flow diagram illustrating an example hazard alert score generation process using one or more intensity measures and one or more recognition-derived confidence weights.

### DETAILED DESCRIPTION OF THE INVENTION

The following description is provided with reference to the accompanying drawings. While specific embodiments are described, it should be understood that the described embodiments are illustrative and not limiting. A person of ordinary skill in the art will recognize that other embodiments may be practiced without departing from the spirit and scope of the invention. Reference numerals are used to designate like elements in the drawings, and the same reference numerals may be used across multiple figures to designate the same or similar components.

As used herein, a “raw metric” includes any sensor-, model-, or verification-derived value indicative of quality, confidence, agreement, error, or skill. A “recognition metric” r is a nonnegative value derived from one or more raw metrics such that larger r indicates higher reliability, higher confidence, higher agreement, higher skill, and/or lower error. A “verification metric” includes a value computed by comparing a forecast output to ground truth or authoritative datasets, including skill measures and decision-performance measures.

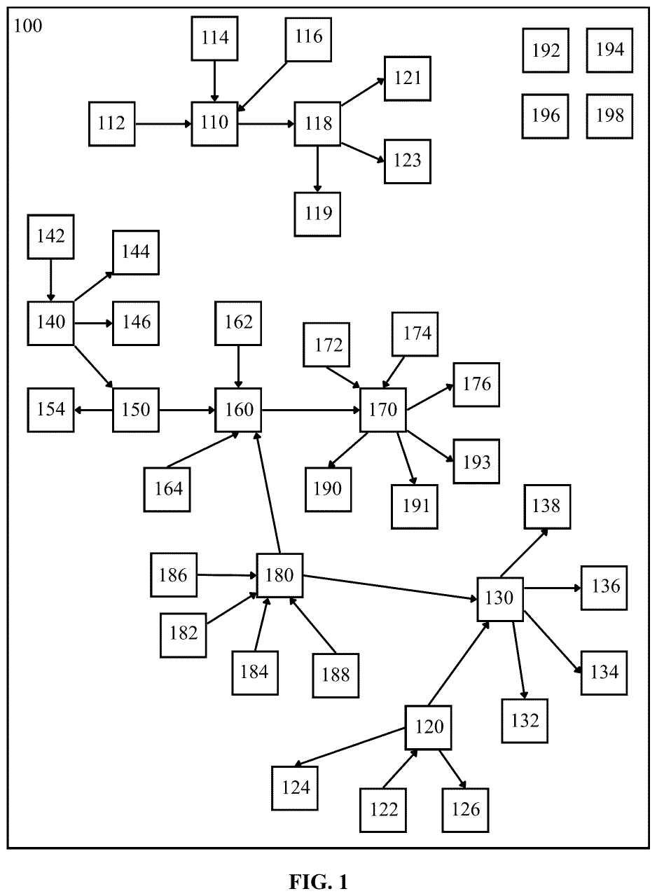

FIG. 1 illustrates an example meteorological recognition processing system 100. The system 100 includes a data ingestion subsystem 110, a recognition atmospheric data filter 120, a recognition pattern matching engine 130, a recognition stability scoring engine 140, a recognition predictive forecasting engine 150, a recognition ensemble weighting engine 160, and a recognition alert engine 170. The system 100 further includes one or more data stores 180 storing, in some embodiments, one or more pattern libraries 182, one or more skill databases 184, configuration data 186, and historical datasets 188. In some embodiments, the system 100 provides one or more outputs 190 including recognition-filtered meteorological fields, pattern detection outputs, forecast fields, ensemble products, alert products, explainability outputs, logs, or combinations thereof.

FIG. 1 illustrates an example meteorological recognition processing system 100. In the example of FIG. 1, a data ingestion layer 110 receives meteorological data 112 from one or more external sources 114 via one or more interfaces 116 and produces normalized inputs 118 for downstream processing. The data ingestion layer 110 can include preprocessing operations 119 such as regridding, quality-control flag parsing, de-aliasing, temporal alignment, spatial alignment, unit normalization, and missing-data handling. In some embodiments, the system 100 includes a recognition atmospheric data filter 120 that receives one or more meteorological fields 122 and one or more raw quality metrics 124 and generates one or more recognition-filtered fields 126. In some embodiments, the system 100 includes a recognition pattern matching engine 130 that produces pattern match outputs 132 including one or more pattern match scores 134 and one or more confidence outputs 136 and optionally one or more detected pattern objects 138. In some embodiments, the system 100 includes a recognition stability scoring engine 140 that receives one or more stability-related variables 142, computes one or more stability recognition metrics 144, and produces one or more stability weights 146. In some embodiments, the system 100 includes a recognition predictive forecasting engine 150 that produces one or more recognition-updated forecast fields 154. In some embodiments, the system 100 includes a recognition ensemble weighting engine 160 that receives one or more candidate forecasts 162 and one or more skill metrics 164. In some embodiments, the system 100 includes a recognition alert engine 170 that receives one or more intensity measures 172 and one or more confidence measures 174 and produces one or more alert products 176. In some embodiments, one or more orchestration or control functions 180 coordinate execution of the modules, including scheduling, batching, and routing of intermediate products. In some embodiments, the system 100 stores or accesses pattern libraries 182, skill databases 184, configuration data 186, and one or more intermediate product stores 188. In some embodiments, the system 100 generates one or more alerts, decisions, or reports 190 and produces explainability outputs 191 and logs 193. In some embodiments, the system 100 is implemented using one or more processors 192, memory 194, network interfaces 196, and storage 198.

In some embodiments, the data ingestion subsystem 110 receives one or more meteorological input streams 112 including satellite-derived fields, radar-derived fields, radiosonde profiles, surface station measurements, aircraft-based measurements, marine buoy measurements, lightning network signals, reanalysis products, and numerical weather prediction model outputs. In some embodiments, the meteorological input streams 112 are received via one or more networks 114 and may be stored in one or more storage systems 116 prior to processing. In some embodiments, the data ingestion subsystem 110 supports ingestion of one or more file or message formats including GRIB, GRIB2, NetCDF, HDF, HDF5, BUFR, or other structured formats, as well as streamed messages delivered via publish-subscribe or queue-based systems.

In some embodiments, recognition-filtered fields, blended forecasts, and alert products are persisted to one or more data stores and/or served to downstream systems via one or more interfaces, including by an application programming interface (API). In some embodiments, outputs are stored or transmitted as structured data objects and/or in meteorological data formats including GRIB2 and NetCDF. In some embodiments, the system produces one or more explainability outputs, logs, and audit records that associate an output product with one or more inputs, one or more recognition metrics, and one or more computed recognition weights.

In some embodiments, the data ingestion subsystem 110 performs one or more preprocessing operations 118 including parsing, unit conversion, temporal alignment, spatial reprojection, vertical interpolation, gridding, tiling, resampling, quality-control flag ingestion, outlier detection, removal or masking of invalid values, and computation of one or more derived fields. In some embodiments, meteorological fields are represented as gridded scalar fields, vector fields, multichannel fields, three-dimensional volumes, vertical profiles, tiles, or combinations thereof. In some embodiments, one or more meteorological fields are represented as object-based structures such as storm cells 119, tracks 121, polygons 123, or other region representations.

In some embodiments, the recognition atmospheric data filter 120 receives one or more meteorological fields 122 and one or more raw quality metrics 124 and generates one or more recognition-filtered fields 126. In some embodiments, the raw quality metrics 124 include one or more of signal-to-noise ratio metrics, sensor confidence scores, retrieval confidence values, temporal consistency metrics, neighborhood consistency metrics, cross-sensor agreement metrics, inverse error metrics, innovation consistency metrics, or combinations thereof. In some embodiments, the raw quality metrics 124 are computed per pixel, per grid cell, per voxel, per vertical level, per tile, per object, or per observation.

In a non-limiting example, a signal-to-noise ratio metric is computed as SNR(x,y,z,t)=sigma_signal/sigma_noise, where sigma_signal is the standard deviation of a meteorological field (or a derived field) over a specified time window and sigma_noise is a noise or baseline variability estimate for the same location and season. In one example, the specified time window is a 6-hour window aligned to the ingestion cadence dt. In some embodiments, r_data is derived from the SNR prior to application of F_cov(·), including by applying one or more mappings that ensure r_data≥0.

In various embodiments, a recognition coverage function maps a nonnegative recognition metric r to a bounded recognition weight. In some embodiments, the recognition coverage function is defined as F_cov(r)=r/(r+X_opt), where r≥0 and X_opt>0. In some embodiments, X_opt is defined as X_opt=phi/pi, where phi=(1+sqrt(5))/2 and pi is the ratio of a circle's circumference to its diameter; in a non-limiting numeric example, X_opt≈0.514933. In some embodiments, for r≥0, the recognition coverage function satisfies F_cov(0)=0, 0≤F_cov(r)<1, monotonic increase in r, and asymptotic approach to 1 for large r, thereby providing a non-amplifying weight that suppresses low-confidence contributions while asymptotically preserving high-confidence contributions.

In some embodiments, the recognition coverage function is applied to generate a recognition weight w that is used as a bounded multiplier, gate, or blending factor in one or more downstream computations. In some embodiments, the recognition weight is computed as w=F_cov(r) and is used to scale one or more field values, derivatives, scores, or contributions such that low-r contributions are suppressed while high-r contributions are preserved without amplification above an unweighted magnitude.

In some embodiments, a raw metric m_raw is mapped into a nonnegative recognition metric r prior to applying the recognition coverage function. In some embodiments, r is computed as r=max(0, m_raw) or r=abs(m_raw). In some embodiments, r is computed by normalizing m_raw according to r=(m_raw−m_min)/(m_max−m_min) followed by r=max(0, r). In some embodiments, r is computed from an error metric e_raw according to r=1/(epsilon+e_raw), where epsilon is a small positive constant. In some embodiments, r is computed from an uncertainty metric u_raw according to r=1/(epsilon+u_raw). In some embodiments, the mapping is selected such that larger r indicates higher reliability, higher confidence, higher skill, higher agreement, or lower error.

In some embodiments, a correlation or similarity score may be bounded to a signed range such as [−1, 1], and the score is mapped to a nonnegative confidence metric prior to applying the recognition coverage function. In some embodiments, Conf_nonneg=max(0, P_match). In some embodiments, Conf_nonneg=(P_match+1)/2. In some embodiments, Conf_nonneg=abs(P_match). In some embodiments, a thresholded confidence is used such that Conf_nonneg=0 when P_match is below a threshold and Conf_nonneg=h(P_match) otherwise, where h is a monotone function producing a nonnegative output.

In some embodiments, the recognition atmospheric data filter 120 computes a recognition weight w_data=F_cov(r_data) for a data recognition metric r_data and computes a recognition-filtered field D_rec. In some embodiments, D_rec(x,y,z,t)=D(x,y,z,t)*F_cov(r_data(x,y,z,t)), where D is a meteorological field value at a spatial coordinate (x,y,z) and time t. In some embodiments, D represents one or more of reflectivity, precipitation rate, integrated vapor transport, temperature, humidity, pressure, wind speed, wind components, turbulence indices, vorticity, divergence, shear, or other fields. In some embodiments, D_rec is computed independently for multiple channels, multiple variables, multiple vertical levels, multiple tiles, multiple regions, or multiple objects.

In some embodiments, meteorological variables include signed values, such as wind components, anomalies, gradients, or vorticity signed about a reference. In such embodiments, recognition weighting is applied in a manner that preserves sign while bounding magnitude, such as S_rec=sign(S)*abs(S)*F_cov(r), where S is a signed value, sign(S) is +1 when S>=0 and −1 when S<0, and r is a nonnegative recognition metric. In some embodiments, wind vectors are represented as components u and v and weighted as u_rec=u*F_cov(r_u) and v_rec=v*F_cov(r_v). In some embodiments, a vector field V is weighted as V_rec=V*F_cov(r), where r is a nonnegative recognition metric shared across components or derived from a vector magnitude, coherence, or agreement measure.

In some embodiments, a multichannel, tensor, or feature-stack field T includes multiple channels c and recognition weighting is applied per channel such that T_rec[c]=T[c]*F_cov(r_c), where r_c is a nonnegative recognition metric for channel c. In some embodiments, r_c is computed from channel-specific quality metrics. In some embodiments, r_c is computed from a shared quality metric for a group of channels. In some embodiments, channels include distinct variables, distinct altitudes, distinct sensor modalities, or distinct derived features.

In some embodiments, the recognition atmospheric data filter 120 computes the data recognition metric r_data using one or more windowed statistics. By way of example, r_data may be based on temporal variance over a time window, spatial variance over a neighborhood window, local coherence of gradients, persistence over a time interval, sensor-reported confidence, cross-sensor agreement, innovation consistency, or combinations thereof. In some embodiments, r_data increases when a measured signal is consistent, coherent, or supported by multiple sources, and decreases when noise dominates or agreement is low.

In some embodiments, the recognition atmospheric data filter 120 computes region-level values by aggregating weighted contributions. In some embodiments, a region-aggregated value is computed as D_rec_region=[sum_i D_i*w_i]/[sum_i w_i], where w_i=F_cov(r_i). In some embodiments, region aggregation is performed for polygon regions, storm objects, track segments, or other grouped representations, and the region aggregation is computed per variable or per channel.

In some embodiments, the recognition pattern matching engine 130 receives one or more recognition-filtered fields 126 and accesses stored pattern representations in the pattern libraries 182 to compute one or more pattern match outputs 132. In some embodiments, a pattern representation includes one or more of spatial templates, multiscale templates, masks, contour signatures, feature vectors, trajectory templates, vector-field templates, embeddings, graphs, or combinations thereof. In some embodiments, the pattern matching engine 130 produces one or more pattern match scores 134 and one or more confidence outputs 136 and optionally produces one or more detected pattern objects 138 including pattern labels, regions, tracks, and timestamps.

In some embodiments, the pattern matching engine 130 computes a normalized cross-correlation score P_match_k for a candidate pattern k as P_match_k=[sum_i D_rec(i)*Pattern_k(i)]/[sqrt(sum_i D_rec(i)\hat{ }2)*sqrt(sum_i Pattern_k(i)\hat{ }2)], where i indexes sample locations. In some embodiments, the score P_match_k is mapped into a nonnegative confidence metric Conf_nonneg prior to applying the recognition coverage function, and a confidence weight w_conf=F_cov(Conf_nonneg) is computed and used to gate downstream operations including forecast updates, ensemble blending, and alert scoring.

In some embodiments, the pattern libraries 182 store patterns corresponding to hazards including tropical cyclone structures, midlatitude cyclone structures, atmospheric river filament structures, squall line structures, mesocyclone structures, jet streak structures, fog bank structures, heat dome structures, flooding precipitation structures, wildfire-weather structures, marine wind-wave structures, or combinations thereof. In some embodiments, the pattern libraries 182 include patterns stored at multiple spatial scales and multiple temporal scales to support matching across different resolutions and lead times.

In some embodiments, the pattern libraries 182 are maintained as versioned datasets, where each pattern representation is associated with metadata including hazard label, region applicability, seasonality, typical intensity range, expected duration, and one or more verification identifiers. In some embodiments, the pattern libraries 182 are updated based on verification events, operator-labeled events, automated labeling from authoritative datasets, or combinations thereof. In some embodiments, candidate patterns are admitted to the pattern libraries 182 after meeting acceptance criteria including persistence, track continuity, agreement across sources, and post-event verification. In some embodiments, the recognition stability scoring engine 140 receives one or more stability-related variables 142 and computes a stability recognition metric 144 and one or more stability weight outputs 146. In some embodiments, stability-related variables include one or more of convective available potential energy, convective inhibition, Richardson number, vertical wind shear, helicity, lapse rate, humidity measures, pressure gradients, potential vorticity, turbulence indices, or other indices.

In some embodiments, a stability weight is computed as S_stab=F_cov(R_stability), where R_stability is a nonnegative stability recognition metric. In some embodiments, R_stability is computed as a combined metric R_stability=g(CAPE, CIN, Ri, |grad(P)|, shear, helicity, lapse_rate, humidity, . . . ), where g yields a nonnegative output. In some embodiments, g is a sum, a weighted sum, a normalized mean, a clipped combination, a max operation, a monotone transformation, or another combination that preserves the intended monotone relationship that larger values indicate greater stability or greater reliability for forecast extrapolation in a defined context.

In some embodiments, the recognition predictive forecasting engine 150 generates one or more recognition-updated forecast fields 154 using temporal derivatives computed from one or more recognition-filtered fields 126 and scaled using one or more stability weights 146. In some embodiments, a first derivative is computed as raw_d1(t)=[D_rec(t)−D_rec(t-dt)]/dt and a stability-scaled first derivative is computed as d1_rec(t)=raw_d1(t)*S_stab(t). In some embodiments, a second derivative is computed as raw_d2(t)=[D_rec(t)−2*D_rec(t−dt)+D_rec(t−2 *dt)]/dt\hat{ }2 and a stability-scaled second derivative is computed as d2_rec(t)=raw_d2(t)*S_stab(t). In some embodiments, a forecast update is computed as D_forecast(t+dt)=D_rec(t)+d1_rec(t)*dt+0.5*d2_rec(t)*dt\hat{ }2.

In some embodiments, the recognition predictive forecasting engine 150 performs recursive updates over multiple time steps and recomputes stability weights as conditions change. In some embodiments, stability weights vary by lead time, variable, region, hazard class, or regime. In some embodiments, additional terms are incorporated including advection terms, forcing terms, constraints, boundary conditions, or combinations thereof, and recognition weighting is applied to one or more such terms to limit unstable growth of low-confidence contributions.

In some embodiments, the recognition ensemble weighting engine 160 receives one or more candidate model forecast fields 162 and one or more skill metrics 164 stored in the skill databases 184. In some embodiments, a raw model weight is computed as w_m_raw=F_cov(skill_m) and a normalized model weight is computed as W_m=w_m_raw/sum_k w_k_raw. In some embodiments, a blended output is computed as D_ensemble=sum_m W_m*D_m, where D_m is a candidate forecast output produced by model or member m.

In some embodiments, the skill metrics 164 are computed from one or more verification measures including anomaly correlation, inverse RMSE, inverse MAE, continuous ranked probability score based measures, Brier skill based measures, fractions skill score based measures, track error inverse measures, intensity error inverse measures, or combinations thereof. In some embodiments, skill metrics are computed by variable, region, lead time, season, hazard class, regime, and model version.

In some embodiments, the skill databases 184 are structured as tables, tensors, or keyed stores that index skill values by one or more dimensions including model identifier, ensemble member identifier, variable identifier, region identifier, lead time, season, hazard class, and regime. In some embodiments, the skill databases 184 store both raw verification statistics and derived skill metrics. In some embodiments, skill values are smoothed, clipped, or regularized to reduce noise and to avoid overweighting short-lived fluctuations.

In some embodiments, the skill databases 184 are updated continuously or periodically using rolling verification windows. In some embodiments, verification events are ingested from authoritative sources and matched to forecast outputs by time, location, and hazard class. In some embodiments, model version identifiers are stored so that skill values are not inadvertently transferred across materially different model configurations.

In some embodiments, the recognition alert engine 170 receives one or more intensity measures 172 and one or more confidence measures 174 and generates one or more alert products 176. In some embodiments, an alert score is computed as Alert_score=Intensity*F_cov(Confidence_nonneg), where Confidence_nonneg is a nonnegative confidence metric derived from one or more of pattern match confidence, observation agreement, ensemble agreement, stability weights, or other confidence signals. In some embodiments, alert issuance is determined by comparing Alert_score to a threshold T_alert, and hysteresis or persistence logic is applied so that alert states do not oscillate when the alert score is near the threshold.

In some embodiments, intensity measures include one or more of reflectivity-based intensity, precipitation rate, integrated vapor transport magnitude, wind gust potential, turbulence index magnitude, hail proxy values, shear magnitude, vorticity magnitude, or other hazard-relevant intensity measures. In some embodiments, confidence measures include one or more of pattern confidence, ensemble agreement, cross-sensor agreement, observation density, stability confidence, or combinations thereof.

In some embodiments, alert products 176 include one or more of map overlays, polygons, track objects, hazard labels, intensity estimates, confidence estimates, lead times, recommended actions, machine-readable messages, or combinations thereof. In some embodiments, the system 100 generates explainability outputs 191 that identify one or more metrics, weights, thresholds, and contributing terms used to compute an alert score, thereby supporting auditability and downstream trust.

In some embodiments, the system 100 generates logs 193 that record the input sources, preprocessing operations, selected normalization mappings, computed recognition metrics, computed recognition weights, and outputs generated at one or more stages. In some embodiments, logs include timestamped summaries that permit replay and verification of how a specific pattern detection, forecast update, ensemble blend, or alert output was generated.

In some embodiments, recognition weighting is used to compute weights for observations or innovations in workflows associated with data assimilation or observation blending, without requiring a separate drawing. In some embodiments, an observation weight is computed as w_obs_i=F_cov(r_obs_i), where r_obs_i is a nonnegative observation recognition metric derived from sensor QC flags, representativeness scores, retrieval confidence, temporal consistency, cross-sensor agreement, or innovation consistency. In some embodiments, a weighted innovation is computed as innov_w_i=innov_i*w_obs_i, where innov_i is an observation-minus-background residual.

In some embodiments, observation weighting is used to modulate the influence of observations within an assimilation update, to modulate blending between observational fields and model background fields, or to modulate quality-control gates that determine whether an observation is accepted, down-weighted, or rejected. In some embodiments, observation weighting is applied at multiple stages, including prior to assimilation, during assimilation, or during post-assimilation analysis.

In some embodiments, the system 100 is implemented in a computing environment including one or more processors 192, memory 194, network interfaces 196, and storage 198. In some embodiments, one or more accelerators are used for high-throughput processing of grids, tiles, and volumes. In some embodiments, the system 100 operates in a cloud environment, an on-premises operations environment, an edge deployment co-located with sensors, or a hybrid environment.

In some embodiments, the system 100 processes data in streaming mode such that meteorological inputs are consumed as they arrive, transformed into normalized internal representations, and passed through one or more recognition-weighted stages with bounded latency. In some embodiments, tiling, batching, parallelization, and multi-threaded execution are used to maintain throughput for high-resolution radar tiles, satellite imagery, or large ensemble sets.

In some embodiments, components communicate through APIs, remote procedure calls, or message buses, and intermediate products and logs are stored in one or more persistent stores. In some embodiments, pattern libraries 182 and skill databases 184 are stored in replicated storage and are cached to reduce query latency.

High-throughput streaming example. In some embodiments, the meteorological input streams are received as publish-subscribe messages via a streaming transport and are processed with bounded latency per analysis cycle. In a non-limiting example, inputs are ingested as stream messages and processed as tiled batches such that end-to-end latency per analysis cycle is less than a predetermined latency budget, and the processing pipeline sustains high-throughput grid operations for large geographic regions.

In some embodiments, the system 100 is used to filter radar reflectivity or radial velocity products to suppress noise and improve downstream convective hazard detection, to detect atmospheric river structures by matching recognition-filtered integrated vapor transport fields against stored filament patterns, to compute stability weights and scale derivative-based forecast updates of short-term precipitation or convective products, to blend multiple candidate model forecasts using recognition-derived skill weights, and to generate confidence-weighted alerts for operational decision support.

In some embodiments, the system 100 provides outputs targeted to specific operational users including aviation users, marine users, emergency management users, agricultural users, energy-grid users, or insurance users. In some embodiments, thresholds, hazard mappings, and output formats are configured by user profile data stored in configuration data 186.

While the disclosure describes particular embodiments using specific meteorological variables, hazards, and metrics, the invention is not limited thereto. In various embodiments, the recognition coverage function is applied to any suitable nonnegative recognition metric and used to produce bounded and monotone weights for filtering, matching, forecasting, blending, alerting, assimilation weighting, or combinations thereof. In various embodiments, the system operates on structured grids, unstructured meshes, tiles, point observations, object tracks, or combinations thereof, and pattern libraries and skill databases are updated periodically, continuously, or in response to verification events.

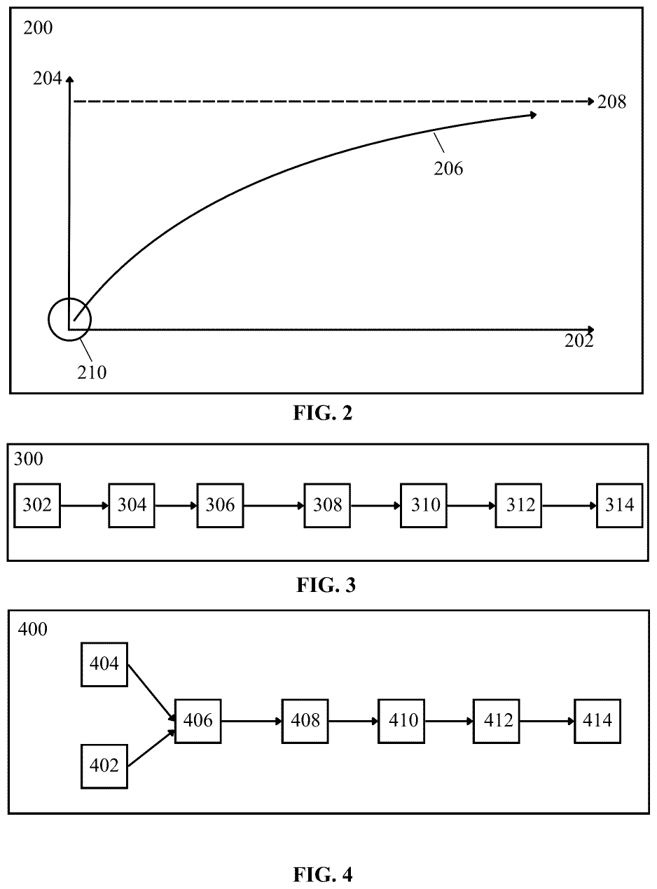

FIG. 2 illustrates an example recognition coverage function plot 200 in which an independent variable axis 202 corresponds to nonnegative recognition metric values r and a dependent variable axis 204 corresponds to recognition weight values F_cov(r), with a recognition coverage curve 206 representing F_cov(r)=r/(r+X_opt), an upper bound 208, and an origin region 210.

FIG. 3 illustrates an example metric-to-weight pipeline 300 in which one or more raw metrics 302 are mapped by a nonnegative mapping operation 304 to produce one or more nonnegative recognition metrics 306, a recognition coverage computation 308 computes one or more recognition weights 310, and one or more application operations 312 apply the recognition weights 310 to produce one or more outputs 314.

FIG. 4 illustrates an example recognition atmospheric data filtering process 400 in which meteorological field inputs 402 and quality metric inputs 404 are received, recognition metrics 406 are determined, recognition weights 408 are computed using the recognition coverage function, a filtering operation 410 computes one or more recognition-filtered fields 412, and one or more filtered field outputs 414 are produced.

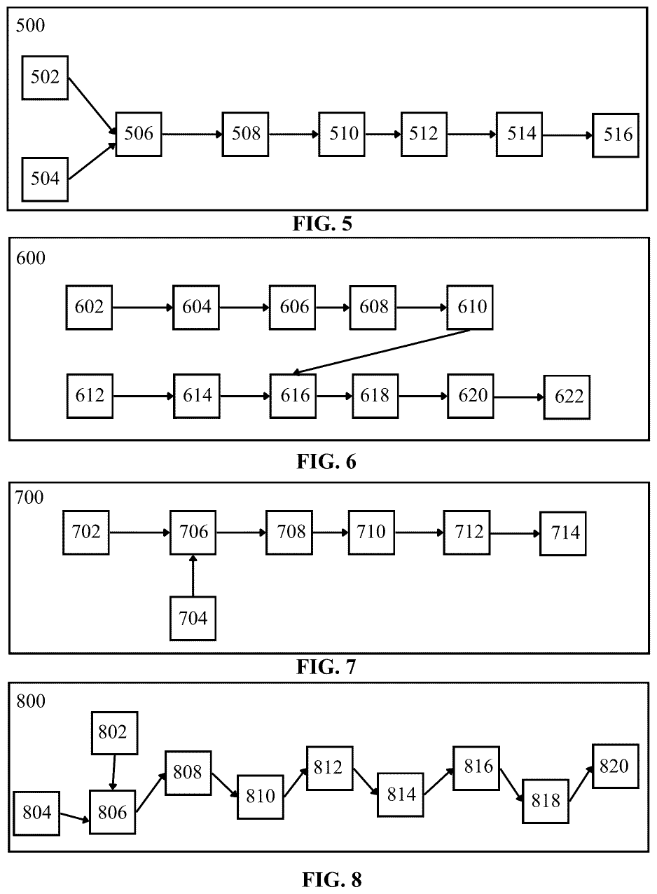

FIG. 5 illustrates an example recognition pattern matching process 500 in which recognition-filtered field inputs 502 are compared to one or more pattern representations 504 using a match score computation 506 to produce one or more pattern match scores 508, a confidence mapping operation 510 produces a nonnegative confidence metric, a recognition coverage computation 512 produces a confidence weight 514, and one or more pattern outputs 516 are generated.

FIG. 6 illustrates an example stability and forecast update process 600 in which stability variable inputs 602 are processed by a stability metric computation 604 to produce a stability recognition metric 606, a stability weighting operation 608 computes a stability weight 610, a derivative computation 612 computes one or more derivative terms 614, a derivative scaling operation 616 produces one or more scaled terms 618, and a forecast update computation 620 produces a forecast output 622.

FIG. 7 illustrates an example ensemble weighting and blending process 700 in which candidate forecast inputs 702 and skill metric inputs 704 are used in a model weight computation 706 to produce raw weights 708, normalized weights 710, and a blending operation 712 generates one or more blended outputs 714.

FIG. 8 illustrates an example alert scoring and issuance process 800 in which intensity inputs 802 and confidence inputs 804 are processed by an alert score computation 806 to produce an alert score 808, an alert decision operation 810 compares the alert score 808 to a threshold 812 and applies hysteresis or persistence logic 814 to determine an alert state 816, and an alert output generation 818 produces one or more alert products 820.

Threshold and window selection (objective criteria). In some embodiments, the threshold 812 and any persistence/hysteresis parameters are selected using an objective calibration protocol. By way of non-limiting example, for a selected hazard class and region, the system evaluates candidate thresholds over a validation dataset with ground-truth hazard outcomes and selects a threshold that satisfies at least one operating-point criterion including: (i) maximizing F1 score, (ii) achieving probability of detection (POD) greater than or equal to a target value while maintaining false alarm ratio (FAR) less than or equal to a target value, or (iii) achieving a receiver-operating-characteristic (ROC) operating point with true-positive rate above a target and false-positive rate below a target. In some embodiments, a persistence window is selected as a number of successive analysis cycles N_p such that an alert state is asserted only after the hazard alert score exceeds the threshold for at least N_p cycles, and is cleared only after the hazard alert score falls below a lower clear threshold for at least N_c cycles. In some embodiments, a forecast update cadence dt is selected from an allowed set based on at least one of sensor refresh rate, model update cadence, or a latency budget, and derivative windows are selected to align to the selected dt.

What is claimed is:

1. A computer-implemented method for meteorological data processing, comprising:
receiving, by one or more processors, meteorological data representing one or more meteorological fields for a geographic region and a time;
determining, by the one or more processors, one or more nonnegative recognition metrics derived from at least one of the meteorological data, one or more derived fields computed from the meteorological data, one or more model outputs, or one or more verification metrics;
computing, by the one or more processors, a recognition weight using a recognition coverage function defined as F_cov(r)=r/(r+X_opt), where r is a nonnegative recognition metric and X_opt is a positive constant; and
applying, by the one or more processors, the recognition weight to filter at least one of the one or more meteorological fields to generate a recognition-filtered field.

2. The method of claim 1, wherein determining the one or more nonnegative recognition metrics comprises mapping a raw metric into a nonnegative value using at least one mapping selected from: r=max(0, m_raw), r=abs(m_raw), r=(m_raw−m_min)/(m_max−m_min) followed by r=max(0, r), or r=1/(epsilon+e_raw) where epsilon is a positive constant.

3. The method of claim 1, wherein the positive constant X_opt satisfies X_opt=phi/pi, where phi=(1+sqrt(5))/2 and pi is the ratio of a circle's circumference to its diameter.

4. The method of claim 1, wherein applying the recognition weight comprises filtering at least one meteorological field to generate a recognition-filtered field according to D_rec=D*F_cov(r_data), where D is a field value and r_data is a nonnegative recognition metric associated with the field value.

5. The method of claim 4, wherein the nonnegative recognition metric associated with the field value is derived from at least one of a signal-to-noise ratio metric, a sensor confidence metric, a retrieval confidence metric, a temporal consistency metric, a neighborhood consistency metric, a cross-sensor agreement metric, an inverse error metric, or an innovation consistency metric.

6. The method of claim 1, further comprising computing a pattern match score based on a recognition-filtered field and a stored pattern representation, and producing a confidence output derived from the pattern match score.

7. The method of claim 6, wherein the pattern match score is a signed similarity value and the confidence output is derived by mapping the signed similarity value into a nonnegative confidence metric using at least one mapping selected from: Conf_nonneg=max(0, P_match), Conf_nonneg=(P_match+1)/2, or Conf_nonneg=abs(P_match).

8. The method of claim 1, further comprising computing a stability weight S_stab=F_cov(R_stability), where R_stability is a nonnegative stability recognition metric derived from at least one stability-related variable.

9. The method of claim 8, wherein the stability-related variable comprises at least one of convective available potential energy, convective inhibition, Richardson number, vertical wind shear, helicity, lapse rate, humidity-related measures, pressure-gradient measures, potential vorticity, or a turbulence-related index.

10. The method of claim 8, further comprising scaling at least one forecast update term using the stability weight, including scaling a first derivative term computed as raw_d1(t)=[D_rec(t)−D_rec(t-dt)]/dt to produce d1_rec(t)=raw_d1(t)*S_stab(t).

11. The method of claim 10, further comprising scaling a second derivative term computed as raw_d2(t)=[D_rec(t)-2D_rec(t-dt)+D_rec(t-2dt)]/dt\hat{ }2 to produce d2_rec(t)=raw_d2(t)*S_stab(t) and generating a forecast update according to D_forecast(t+dt)=D_rec(t)+d1_rec(t)dt+0.5d2_rec(t)*dt\hat{ }2.

12. The method of claim 1, further comprising computing an ensemble blending weight for each of a plurality of candidate forecast sources using w_m_raw=F_cov(skill_m) and W_m=w_m_raw/sum_k w_k_raw, where skill_m is a nonnegative skill metric associated with a candidate forecast source.

13. The method of claim 12, wherein the nonnegative skill metric is derived from at least one verification measure selected from anomaly correlation, inverse root-mean-square error, inverse mean absolute error, a continuous ranked probability score-based measure, a Brier skill-based measure, a fractions skill score-based measure, a track error inverse measure, or an intensity error inverse measure.

14. The method of claim 1, further comprising computing a hazard alert score according to Alert_score=Intensity*F_cov(Confidence_nonneg), where Intensity is a hazard intensity measure and Confidence_nonneg is a nonnegative confidence metric.

15. The method of claim 14, further comprising determining whether to issue a hazard alert by comparing the hazard alert score to a threshold and applying hysteresis or persistence logic to reduce oscillation of alert states.

16. The method of claim 15, further comprising selecting the threshold for issuing the hazard alert based on an objective selection protocol that evaluates at least one performance criterion over historical data, the at least one performance criterion including at least one of an F1 score, a probability of detection, a false alarm rate, or a receiver operating characteristic operating point.

17. The method of claim 15, wherein the persistence logic comprises requiring a persistence count N_p indicating that the hazard alert score satisfies an issuance condition for at least N_p evaluation cycles prior to issuing the hazard alert, and requiring a clear count N_c indicating that the hazard alert score satisfies a clear condition for at least N_c evaluation cycles prior to clearing the hazard alert.

18. The method of claim 1, further comprising computing an observation weight for an observation using w_obs=F_cov(r_obs) where r_obs is a nonnegative observation recognition metric, and applying the observation weight to modulate at least one of an observation contribution or an observation-minus-background residual.

19. A meteorological processing system, comprising:
one or more processors; and
memory storing instructions that, when executed by the one or more processors, cause the one or more processors to perform the method of claim 1.

20. A non-transitory computer-readable medium storing instructions that, when executed by one or more processors, cause the one or more processors to perform the method of claim 1.
